(19) United States
(12) Patent Application Publication
(10) Pub. No.: US 2026/0035580 A1
(43) Pub. Date: Feb. 5, 2026

(54) A Curable Inkjet Composition for the Manufacturing of Printed Circuit Boards

(71) Applicant: Agfa-Gevaert NV, Mortsel (BE)

(72) Inventors: Marion Sauvageot, Mortsel (BE); Jeannette Munyeshyaka, Mortsel (BE); Mitch Matthys, Mortsel (BE)

(73) Assignee: Agfa-Gevaert NV, Mortsel (BE)

(21) Appl. No.: 18/996,170

(22) PCT Filed: Jul. 18, 2023
(86) PCT No.: PCT/EP2023/069899

§ 371 Date: Jan. 17, 2025

(30) Foreign Application Priority Data
Jul. 19, 2022 (EP) 22185667.7

(51) Int. Cl. C09D 11/38; H05K 3/28

(52) U.S. Cl. CPC C09D 11/38; H05K 3/287

(57) ABSTRACT

A curable inkjet composition for a printed circuit board, comprising (a) one or more thermal cross-linking agent selected from the group consisting of an unblocked isocyanate, a blocked isocyanate and a triazine compound; and (b) at least two photopolymerizable compounds, characterized in that at least one polymerizable compound has a chemical structure according to General Formula (I) wherein R1, R2, R3, and R4 independently from each other represent hydrogen or a substituted or unsubstituted C₁ to C₁₀ alkyl group.

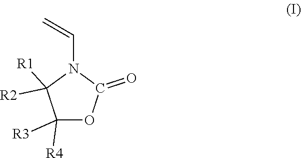

### TECHNICAL FIELD

The present invention relates to a curable composition for use as an ink jet composition in the manufacturing of electronic devices. The invention also relates to a cured product of said composition.

### BACKGROUND ART

Printed Circuit Boards (PCBs) are traditionally manufactured in an extensive process including multiple photolithographic and etching steps, thereby generating a lot of waste. In order to reduce the amount of process steps, production costs, and waste, there is an increased interest in digitalizing the PCB manufacturing workflow.

Inkjet printing is a preferred digital manufacturing technology for several PCB production steps, such as the application of the etch resist and the solder mask, or printing of the legend.

The PCB solder mask, or solder resist, acts as an insulator between the copper traces, and prevents the formation of solder bridges. Moreover, it plays an important role in protecting the board against oxidation triggered by outer influences, such as weather conditions, temperature variations, and humidity. When mechanical defects occur in the solder mask due to exposure to these external conditions, the protective and insulating function of the solder mask can be negatively affected. Therefore, the main objective for producing an effective solder mask is to provide a good resistance against the conditions to which it is exposed.

For the production of a PCB solder mask via ink jet, an important requirement is that the solder mask must be able to withstand the operating conditions during typical finishing processes, such as ENIG plating (ENIG plating resistance), wherein severe and varying conditions (pH and temperature) are used.

EP4032958 (Agfa-Gevaert) discloses a radiation curable inkjet ink to prepare a solder mask, wherein the ink comprises a polymerizable compound, a phenolic resin and a thermal cross-linking agent. The combination of these compounds ensures a good adhesion and a good ENIG plating resistance.

EP-A 1624001 (Taiyo Ink Manufacturing) discloses an inkjet ink for solder mask printing comprising a (meth)acrylate monomer including a thermosetting functional group. WO2020/109769 (Electra Polymers) discloses an inkjet ink for solder mask printing comprising a reactive monomer, an oligomer of prepolymer containing at least one epoxy or oxetane functional group, a free radical polymerizable compound, a thermal cross-linking agent and a radical initiator.

EP-A 3778793 (Taiyo Ink Manufacturing) discloses an inkjet ink for solder mask printing, comprising a photopolymerizable monomer with a cyclic skeleton and a shrinkage of less than 10%, which results in an improved heat resistance before ENIG plating.

Finally, it is beneficial that the inkjet ink has a good LED sensitivity. An ink with a good LED sensitivity is desired because an improved curing efficiency is leading to a better image quality and line sharpness. It is often the case that a good LED sensitivity is also indicative of good mechanical properties of the cured ink, such as hardness and strength. Therefore, there is a need for inkjet inks for use in a PCB manufacturing process combining a good LED sensitivity and a good ENIG plating resistance.

### SUMMARY OF INVENTION

It is an object of the present invention to provide an inkjet composition for use in a PCB manufacturing process having a good ENIG plating resistance. The object of the invention is realized by the curable composition as defined in claim 1. It is a further object of the invention to provide an inkjet composition for use in a PCB manufacturing process having a good ENIG plating resistance, combined with a good LED sensitivity.

Further objects of the invention will become apparent from the description hereinafter.

### DESCRIPTION OF EMBODIMENTS

### Definitions

The term “monofunctional” in e.g. monofunctional polymerizable compound means that the polymerizable compound includes one polymerizable group.

The term “difunctional” in e.g. difunctional polymerizable compound means that the polymerizable compound includes two polymerizable groups.

The term “polyfunctional” or “multifunctional” in e.g. polyfunctional polymerizable compound means that the polymerizable compound includes more than two polymerizable groups.

The term “alkyl” means all variants possible for each number of carbon atoms in the alkyl group i.e. methyl, ethyl, for three carbon atoms: n-propyl and isopropyl; for four carbon atoms: n-butyl, isobutyl and tertiary-butyl; for five carbon atoms: n-pentyl, 1,1-dimethyl-propyl, 2,2-dimethylpropyl and 2-methyl-butyl, etc.

Unless otherwise specified a substituted or unsubstituted alkyl group is preferably a C₁ to C₆-alkyl group.

Unless otherwise specified a substituted or unsubstituted alkenyl group is preferably a C₂ to C₆-alkenyl group.

Unless otherwise specified a substituted or unsubstituted alkynyl group is preferably a C₂ to C₆-alkynyl group.

Unless otherwise specified a substituted or unsubstituted alkaryl group is preferably a phenyl or naphthyl group including one, two, three or more C₁ to C₆-alkyl groups.

Unless otherwise specified a substituted or unsubstituted aralkyl group is preferably a C₇ to C₂₀-alkyl group including a phenyl group or naphthyl group.

Unless otherwise specified a substituted or unsubstituted aryl group is preferably a phenyl group or naphthyl group

Unless otherwise specified a substituted or unsubstituted heteroaryl group is preferably a five- or six-membered ring substituted by one, two or three oxygen atoms, nitrogen atoms, sulphur atoms, selenium atoms or combinations thereof.

The term “substituted”, in e.g. substituted alkyl group means that the alkyl group may be substituted by other atoms than the atoms normally present in such a group, i.e. carbon and hydrogen. For example, a substituted alkyl group may include a halogen atom or a thiol group. An unsubstituted alkyl group contains only carbon and hydrogen atoms

Unless otherwise specified a substituted alkyl group, a substituted alkenyl group, a substituted alkynyl group, a substituted aralkyl group, a substituted alkaryl group, a substituted aryl and a substituted heteroaryl group are preferably substituted by one or more constituents selected from the group consisting of methyl, ethyl, n-propyl, isopropyl, n-butyl, isobutyl and tertiary-butyl, ester, amide, amine, ether, thioether, ketone, aldehyde, sulfoxide, sulfone, sulfonate ester, sulphonamide, —Cl, —Br, —I, —OH, —SH, —CN and —NO₂.

### Curable Inkjet Composition

The curable composition according to the present invention comprises one or more thermal cross-linking agent selected from an unblocked isocyanate, a blocked isocyanate and a triazine compound; and at least two photopolymerizable compounds as described below.

The composition is preferably a radiation-curable composition. Any type of radiation may be applied, but preferred radiation types are UV-light and UV-LED light. Therefore, the curable composition according to the present invention is preferably a UV-curable composition.

In a preferred embodiment, the composition according to the present invention comprises a mixture of UV-curable compounds and thermal cross-linking agents. Therefore, the curable composition according to the present invention is preferably also a thermally curable composition. Any type of heat source may be used for the thermal curing step, but preferably the thermal curing is performed in an oven.

The two curing processes, thermal and UV, can take place simultaneously or sequentially. This so-called dual-cure principle results in the formation of an interpenetrating polymer network, which the inventors believe to be the reason for the observed superior mechanical properties compared to the individually cured polymer networks.

The curable composition according to the invention is preferably applied as an inkjet ink.

For reliable industrial inkjet printing, the viscosity of the curable inkjet ink is preferably no more than 20 mPa·s at 45° C., more preferably between 1 and 18 mPa·s at 45° C., and most preferably between 5 and 15 mPa·s at 45° C., all at a shear rate of 1000 s⁻¹.

A preferred jetting temperature is between 1° and 70° C., more preferably between 2° and 55° C., and most preferably between 25 and 50° C.

For good image quality and adhesion, the surface tension of the curable inkjet ink is preferably in the range of 18 to 70 mN/m at 25° C., more preferably in the range of 20 to 40 mN/m at 25° C.

### Photopolymerizable Compounds

The curable inkjet composition according to the present invention comprises at least one photopolymerizable compound having a chemical structure according to General Formula I.

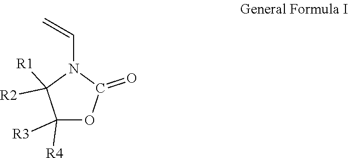

wherein R1, R2, R3 and R4 independently from each other represent hydrogen, alkyl, cycloalkyl, or aryl and combinations thereof, any of which may be interrupted by heteroatoms. Any of R1 to R4 may represent the necessary atoms for forming a five- or six-membered ring.

Preferably R1, R2, R3 and R4 are independently from each other selected from hydrogen or a substituted or unsubstituted C₁ to C₁₀ alkyl group.

Preferred compounds are disclosed in WO 2015/022228 (BASF) and U.S. Pat. No. 4,831,153 (DOW CHEMICAL).

Cyclic compounds according to General Formula I are often referred to as oxazolidinones. A particularly preferred oxazolidinone is N-vinyl-5-methyl-2-oxazolidinone, also referred to as vinyl methyl oxazolidinone, or VMOX, General Formula II.

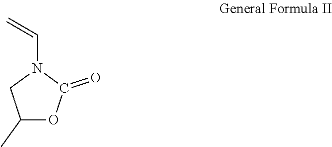

Including a compound according to General Formula I or II improves the LED sensitivity of the cured ink layer. The amount of the compound according to General Formula I or II is preferably from 1 to 40 wt %, more preferably from 2.5 to 30 wt %, and most preferably from 5 to 20 wt % based on the total weight of the curable inkjet composition. Moreover, compounds according to General Formula I or II have a low viscosity compared to other N-vinyl compounds, which makes them especially suitable for ink jet printing.

The curable composition according to the present invention may also comprise other photopolymerizable compounds.

The photopolymerizable compounds are preferably free radical polymerizable compounds. The free radical polymerizable compounds may be monomers, oligomers and/or prepolymers. These monomers, oligomers and/or prepolymers may possess different degrees of functionality, i.e. a different amount of free radical polymerizable groups. A mixture including combinations of mono-, di-, tri- and higher functional monomers, oligomers and/or prepolymers may be used. The viscosity of the curable inkjet ink may be adjusted by varying the ratio between the monomers and oligomers.

The photopolymerizable compounds may also comprise functional groups, such as thiols, hydroxyls, amines, sulfonic acids, phosphoric acids, and carboxylic acids. Examples of hydroxyl-functionalized polymerizable compounds are those listed in paragraphs [0028] to [0029] in US2015/0090482A.

Preferred photopolymerizable compounds are those listed in paragraphs [0106] to [0115] in EP-A 1911814.

Especially preferred monofunctional photopolymerizable compounds are selected from the group consisting of 2-ethylhexyl acrylate, lauryl acrylate, stearyl acrylate, 3,3,5-trimethylcyclohexyl acrylate, isobornyl acrylate, 2-phenoxyethyl acrylate, and acryloyl morpholine.

The curable inkjet composition preferably contains one or more multifunctional photopolymerizable compounds.

Preferred multifunctional photopolymerizable compounds are selected from the group consisting of polyethyleneglycol diacrylate, hexanediol diacrylate, trimethylolpropane triacrylate, pentaerythritol tetraacrylate, dipentaerythritol pentaacrylate, polyester acrylate oligomer and polyether acrylate oligomer.

The curable inkjet composition may further contain a photopolymerizable compound containing a vinyl group selected from the group consisting of a vinylether group and an N-vinyl amide group.

Preferred examples of photopolymerizable compounds containing a vinylether group or an N-vinylamide group are those listed in paragraphs [0047] to [0056] in EP-A 3686251.

A particularly preferred vinylether containing photopolymerizable compound is 2-(2-vinyloxyethoxy)ethyl acrylate, as it is advantageous in providing a good balance between the curability and the viscosity of the curable inkjet composition. The amount of 2-(2-vinyloxyethoxy)ethyl acrylate is preferably at least 5 wt %, more preferably at least 7.5 wt % and most preferably at least 10 wt % based on the total weight of the curable inkjet composition.

Particularly preferred vinylamide containing photopolymerizable compounds are N-vinyl-2-pyrrolidone and N-vinylcaprolactam as they combine a high Tg with a good ink curability and a good adhesion of a cured ink layer to a recording medium.

A combination of any of the above photopolymerizable compounds may be used.

### Thermal Cross-Linking Agent

The curable composition of the present invention comprises one or more thermal cross-linking agent selected from the group consisting of unblocked isocyanates, blocked isocyanates and triazine compounds. The presence of a thermal cross-linking agent may improve the adhesion of the obtained coating film after soldering or ENIG plating.

The thermal cross-linking agent may be monofunctional, difunctional or multifunctional.

The inkjet composition may comprise a mixture of different thermal cross-linking agents.

Typical thermal cross-linking agents are oxiranes, oxetanes, melamine-formaldehyde resins, urea-formaldehyde resins, benzoguanamine-formaldehyde resins, cyclic carbonate compounds, carbodiimides, isocyanates, blocked isocyanates, triazine compounds and combinations thereof.

Preferred thermal cross-linking agents are isocyanate compounds. Isocyanate compounds are preferably used in combination with a compound comprising active hydrogen functionalities, including, without limitation, alcohols, thiols, amines, water, or combinations thereof. Atmospheric moisture may also cause isocyanate cross-linking. When atmospheric moisture is reacting with an isocyanate, it may not be necessary to prepare an ink combining the isocyanate compound with a compound comprising active hydrogen functionalities.

The isocyanate compound may be an aliphatic, an alicyclic or an aromatic isocyanate. In case the isocyanate compound is a multifunctional isocyanate, it may comprise a combination of aliphatic, alicyclic or aromatic isocyanate functionalities.

Examples of aliphatic isocyanates include, without limitation, 1,6-hexamethylene diisocyanate (HDI or HMDI), isophorone diisocyanate (IPDI), 1,3-(isocyanatomethyl)cyclohexane (hydrogenated XDI), lysine diisocyanate (LDI), 2,2,4-trimethyl hexamethylene diisocyanate (TMDI), and dimeryl diisocyanate (DDI).

Examples of alicyclic isocyanates include, without limitation, isophorone diisocyanate (IPDI), methylcyclohexane 2,4-(2,6)-diisocyanate (hydrogenated TDI), and 4,4′-methylenebis(cyclohexylisocyanate) (hydrogenated MDI).

Examples of aromatic isocyanates include, without limitation, toluene diisocyanate (TDI), 1,5-naphthalene diisocyanate (NDI), 4,4′-di-phenyl-methanediisocyanate (MDI) and xylylene diisocyanate (XDI).

Examples also include adducts (e.g. trimethylol propane adducts), uretdiones, biurets, and isocyanurates of the isocyanates listed above.

The isocyanate compound may be blocked or unblocked, preferably blocked.

A blocked isocyanate can be obtained by reacting an isocyanate with a blocking agent of choice. Such a blocking agent is a protective group, which is cleaved off at elevated temperatures, for example during a thermal curing process. The blocking agent can be chosen such that it will cleave off at a certain temperature, the so-called de-blocking temperature. Using a blocked isocyanate typically improves the storage stability of the inkjet ink.

Examples of the blocking agent include alcohols such as ethanol, n-propanol, isopropanol, t-butanol, and isobutanol; phenols such as phenol, chlorophenol, cresol, xylenol, and p-nitrophenol; alkylphenols such as p-t-butylphenol, p-sec-butylphenol, p-sec-amylphenol, p-octylphenol, and p-nonylphenol; basic nitrogen-containing compounds such as 3-hydroxypyridine, S-hydroxyquinoline, and 8-hydroxyquinaldine; active methylene compounds such as diethyl malonate, ethyl acetoacetate, and acetylacetone; acid amides such as acetamide, acrylamide, and acetanilide; acid imides such as succinimide and maleic imide; imidazoles such as 2-ethylimidazole and 2-ethyl-4-methylimidazole; pyrazoles such as pyrazole, 3-methylpyrazole, and 3,5-dimethylpyrazole; lactams such as 2-pyrrolidone and 8-caprolactam; oximes of ketone or aldehyde, such as acetoxime, methyl ethyl ketone oxime, cyclohexanone oxime, and acetaldoxime; ethyleneimine; and bisulfite.

Hindered secondary amines may be used as blocking agents for toxicology reasons. Preferred hindered secondary amines are selected form the group consisting of ethyl-tert-butyl amine, diisopropyl amine, 2,6-dimethyl-piperidine, ethyl-isopropyl amine, di-tert-butyl amine and diisobutyl amine.

A preferred blocked isocyanate compound is a blocked HDI oligomer or a blocked IPDI oligomer. Such an oligomer can be for example a trimethylol propane adduct, a biuret, or an isocyanurate.

Particularly preferred blocked isocyanate compounds are Trixene BI 7960, a HDI biuret blocked with 3,5-dimethylpyrazole, commercially available from Lanxess and Trixene BI7982, a HDI trimer blocked with 3,5-dimethylpyrazole, commercially available from Lanxess.

Other preferred thermal cross-linking agents are triazine compounds having a triazine skeleton. The triazine moiety is believed to contribute to the mechanical properties and heat resistance of the cured film. Any triazine compound having thermal cross-linking properties may be used.

A preferred triazine compound has a chemical structure according to General Formula III,

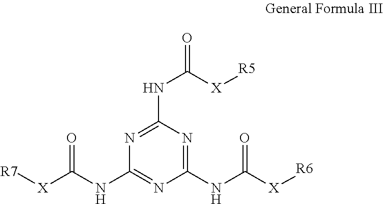

wherein X represents N, O, S, P or C;
R5, R6 and R7 independently from each other represent a substituted or unsubstituted alkyl group;
X preferably represents O or C, most preferably O.

Preferably, R5, R6 and R7 independently from each other represent a substituted or unsubstituted C1-C8 alkyl group. More preferably, R5, R6 and R7 independently from each other represent a group selected from the group consisting of methyl, ethyl, n-propyl, i-propyl, butyl, n-octyl, 2-ethyl hexyl.

Preferred triazine compounds according to General Formula III and their preparation method are disclosed in U.S. Pat. No. 5,084,541 (American Cyanamid Company).

Preferred triazine compounds according to General Formula III are commercially available from Allnex under the name Cymel® NF 2000A and from BASF under the name Larotact® 150.

The inkjet ink according to the present invention preferably includes a blocked isocyanate compound or a triazine compound according to General Formula III.

More preferably, the inkjet ink includes both a blocked isocyanate and a triazine compound according to General Formula III.

The total amount of thermal cross-linking agents is preferably from 0.5 up to 20 wt %, more preferably from 1 to 15 wt %, most preferably from 2 to 12 wt %, all relative to the total weight of the inkjet inks.

The amount of the blocked isocyanate compound is preferably from 0.1 to 12.5 wt %, more preferably from 0.5 to 10 wt %, most preferably from 1 to 8 wt %, all relative to the total weight of the inkjet ink.

The amount of the triazine compound is preferably from 0.1 to 5 wt %, more preferably from 0.5 to 4 wt %, most preferably from 1 to 3 wt %, all relative to the total weight of the inkjet ink.

It has been observed that the presence of thermal cross-linking agents improves various solder resist properties such as resistance to heat, hardness, resistance to soldering heat, resistance to chemicals, electrical insulating properties, and resistance to electroless plating and immersion plating.

### Phenolic Resins

The curable composition according to the present invention may comprise one or more phenolic resins.

The phenolic resin is preferably a phenolic group functionalized polymer, selected from a polyacrylate, a polymethacrylate or polystyrene.

Preferred phenolic resins are poly(4-hydroxystyrene) and derivatives thereof.

Particularly preferred phenolic resins are disclosed in US20060099531 (DuPont Electronic Polymers L.P.), in particular the phenolic resins having structures I, II, III and IV disclosed in paragraph 0018.

The amount of the phenolic resin is preferably from 0.5 to 20 wt %, more preferably from 1 to 15 wt %, most preferably from 2.5 to 10 wt %, all relative to the total weight of the inkjet ink.

### Photoinitiators

The curable inkjet composition preferably includes a photoinitiator, preferably a free radical photoinitiator.

A free radical photoinitiator is a chemical compound that initiates polymerization of monomers and oligomers when exposed to actinic radiation by the formation of a free radical. A Norrish Type I initiator is an initiator which cleaves after excitation, yielding the initiating radical immediately. A Norrish type II-initiator is a photoinitiator which is activated by actinic radiation and forms free radicals by hydrogen abstraction from a second compound that becomes the actual initiating free radical. This second compound is called a polymerization synergist or co-initiator. Both type I and type II photoinitiators can be used in the present invention, alone or in combination.

Suitable photoinitiators are disclosed in CRIVELLO, J. V., et al. Photoinitiators for Free Radical, Cationic and Anionic Photopolymerization. 2nd edition. Edited by BRADLEY, G. London, UK: John Wiley and Sons Ltd, 1998. p. 276-293.

Specific examples of free radical photoinitiators may include, but are not limited to, the following compounds or combinations thereof: benzophenone and substituted benzophenones; 1-hydroxycyclohexyl phenyl ketone; thioxanthones such as isopropylthioxanthone; 2-hydroxy-2-methyl-1-phenylpropan-1-one; 2-benzyl-2-dimethylamino-(4-morpholinophenyl) butan-1-one; benzyl dimethylketal; 2-methyl-1-[4-(methylthio) phenyl]-2-morpholinopropan-1-one; 2,2-dimethoxy-1, 2-diphenylethan-1-one or 5,7-diiodo-3-butoxy-6-fluorone.

A preferred photoinitiator is a thioxanthone compound, such as Darocur ITX, an isomeric mixture of 2- and 4-isopropylthioxanthone.

Another preferred photoinitiator is an acylphosphine oxide compound. The acylphosphine oxide compound may be selected from the group consisting of a mono-acylphosphine oxide and a di-acylphosphine oxide. Preferred acylphosphine oxide photoinitiators are diphenyl(2,4,6-trimethylbenzoyl)phosphine oxide (TPO), ethyl (2,4,6-trimethylbenzoyl) phenyl phosphinate (TPO-L), phenylbis(2,4,6-trimethylbenzoyl)phosphine oxide) (BAPO), bis (2,6-dimethyl-benzoyl)-2,4,4-trimethylpentylphosphine oxide and 2,4,6-trimethoxybenzoyl-diphenylphosphine oxide.

Other preferred photoinitiators are α-hydroxy-ketone Type I photoinitiators such as for example oligo[2-hydroxy-2-methyl-1-[4-(1-methylvinyl-phenyl]propanone] available as Esacure® KIP IT from IGM resins.

A preferred amount of photoinitiator is from 0.2 up to 20 wt %, more preferably from 0.5 up to 10 wt %, most preferably from 1 up to 8 wt %, particularly preferred from 1.5 up to 6 wt %, all relative to the total weight of the curable inkjet composition.

In order to increase the photosensitivity further, the curable inkjet composition may additionally contain co-initiators. Suitable examples of co-initiators can be categorized in three groups:
(1) tertiary aliphatic amines such as methyldiethanolamine, dimethylethanolamine, triethanolamine, triethylamine and N-methylmorpholine;
(2) aromatic amines such as amylparadimethyl-aminobenzoate, 2-n-butoxyethyl-4-(dimethylamino) benzoate, 2-(dimethylamino)-ethylbenzoate, ethyl-4-(dimethyl-amino)benzoate, and 2-ethylhexyl-4-(dimethylamino)benzoate; and
(3) (meth)acrylated amines such as dialkylamino alkyl(meth)acrylates (e.g., diethyl-aminoethylacrylate) or N-morpholinoalkyl-(meth)acrylates (e.g., N-morpholinoethyl-acrylate).

Preferred co-initiators are aminobenzoates.

A preferred low molecular aminobenzoate is Genocure® EPD from RAHN.

Particularly preferred aminobenzoate co-initiators are selected from the group consisting of polymerisable, oligomeric and polymeric aminobenzoate co-initiators.

Polymerisable co-initiators are disclosed in EP-A 2033949 (Agfa Graphics N.V.).

In a more preferred embodiment, the aminobenzoate co-initiators are oligomeric aminobenzoate derivatives.

Particularly preferred aminobenzoates are polyether derivatives of aminobenzoates, wherein the polyether is selected from the group consisting of poly(ethylene oxide), poly(propylene oxide), copolymers thereof, and poly(tetrahydrofuran), ethoxylated or propoxylated neopentyl glycol, ethoxylated or propoxylated trimethylpropane and ethoxylated or propoxylated pentaerythritol.

Preferred oligomeric aminobenzoates are disclosed in W01996/33157 (Lambson Fine Chemicals Ltd.) and WO2011/030089 (Sun Chemicals B.V.). Typical examples of polyethylene glycol bis p-dimethylaminobenzoate are OMNIPOL ASA, commercially available from IGM Resins and Speedcure 7040, commercially available from Lambson Fine Chemicals.

Other oligomeric or polymeric co-initiators are for example ESACURE A198, a polyfunctional amine from IGM and SARTOMER® CN3755, an acrylated amine co-initiator from ARKEMA.

### Inhibitors

The curable inkjet composition may contain at least one inhibitor for improving the thermal stability of the ink.

Suitable polymerization inhibitors include phenol type antioxidants, hindered amine light stabilizers, phosphor type antioxidants, hydroquinone monomethyl ether commonly used in (meth)acrylate monomers, and hydroquinone, t-butyl-catechol, pyrogallol, 2,6-di-tert.butyl-4-methylphenol (=BHT) may also be used.

Suitable commercial inhibitors are, for example, Sumilizer™ GA-80, Sumilizer™ GM and Sumilizer™ GS produced by Sumitomo Chemical Co. Ltd.; Genorad™ 16, Genorad™18 and Genorad™ 20 from Rahn AG; Irgastab™UV10 and Irgastab™ UV22, Tinuvin™ 460 and CGS20 from Ciba Specialty Chemicals; Floorstab™ UV range (UV-1, UV-2, UV-5 and UV-8) from Kromachem Ltd, Additol™ S range (S100, S110, S120 and S130) from Cytec Surface Specialties.

Since excessive addition of these polymerization inhibitors may lower the curing speed, it is preferred that the amount capable of preventing polymerization is determined prior to blending. The amount of a polymerization inhibitor is preferably lower than 5 wt %, more preferably lower than 3 wt % of the total curable inkjet composition.

### Adhesion Promotor

The curable inkjet composition may include an adhesion promoter to further optimize the adhesion of the cured composition to various surfaces, in particular a copper surface.

Any adhesion promoter may be used, for example those disclosed in WO2004/026977 and WO2004/105 both from AVECIA; WO2017/009097 and WO2020/104302 both from Agfa-Gevaert; and WO2018/087059, WO2018087052 WO2018087056 and WO2018087055, all from Agfa-Gevaert/Electra Polymers.

The curable inkjet composition may include one adhesion promoter or a combination of two, three or more different adhesion promoters.

The total amount of adhesion promoters is preferably between 0.1 and 20 wt %, more preferably between 0.5 and 15 wt %, most preferably between 1 and 10 wt %, all relative to the total weight of the inkjet composition.

However, it has been observed that an inkjet composition according to the present invention may have a sufficient adhesion, even after soldering, gold or ENIG plating, in the absence of an adhesion promoter. As the presence of adhesion promoters may result in a worse stability of the inkjet ink, the curable inkjet composition according to the present invention preferably does not contain an adhesion promoter.

### Flame Retardant

The curable inkjet composition preferably comprises a flame retardant.

Preferred flame retardants are inorganic flame retardants, such as Alumina Trihydrate and Boehmite; organo-phosphor compounds, such as organo-phosphates (e.g. triphenyl phosphate (TPP), resorcinol bis (diphenylphosphate) (RDP), bisphenol A diphenyl phosphate (BADP), and tricresyl phosphate (TCP)); organo-phosphonates (e.g. dimethyl methylphosphonate (DMMP)); and organophosphinates (e.g. aluminium dimethylphosphinate).

Preferred flame retardants are disclosed in WO2019/121098.

### Colorants

The curable inkjet composition may be a substantially colourless inkjet ink or may include at least one colorant. For example, when the inkjet ink is used as etch resist, the colorant makes the temporary mask clearly visible to the manufacturer of conductive patterns, allowing a visual inspection of quality. When the inkjet ink is used to apply a solder mask it typically contains a colorant. A preferred colour for a solder mask is green, however other colours such as black or red may also be used.

The colorant may be a pigment or a dye.

A colour pigment may be chosen from those disclosed by HERBST, Willy, et al. Industrial Organic Pigments, Production, Properties, Applications. 3rd edition. Wiley-VCH, 2004. ISBN 3527305769. Suitable pigments are disclosed in paragraphs [0128] to [0138] of WO2008/074548.

Pigment particles in inkjet inks should be sufficiently small to permit free flow of the ink through the inkjet-printing device, especially at the ejecting nozzles. It is also desirable to use small particles for maximum colour strength and to slow down sedimentation. Most preferably, the average pigment particle size is not larger than 150 nm. The average particle size of pigment particles is preferably determined with a Brookhaven Instruments Particle Sizer BI90plus based upon the principle of dynamic light scattering.

Generally, dyes exhibit a higher light fading than pigments, but cause no problems on jettability. It was found that anthraquinone dyes exhibit only minor light fading under the normal UV curing conditions used in UV curable inkjet printing. In a preferred embodiment, the colorant in the curable inkjet ink is an anthraquinone dye, such as Macrolex™ Blue 3R (CASRN 325781-98-4) from LANXESS.

Other preferred dyes include crystal violet and a copper phthalocyanine dye.

It is possible to combine different colorants to obtain the desired colour, or to improve the dispersion stability. A preferred combination of colorants to obtain a green solder mask is a combination of a blue and a yellow colorant. In a particularly preferred embodiment, a combination of pigment yellow 150 and pigment blue 15:4 is used.

In a preferred embodiment, the colorant is present in an amount of 0.5 to 6.0 wt %, more preferably 0.75 to 2.5 wt %, based on the total weight of the curable inkjet ink.

### Polymeric Dispersants

If the colorant in the curable inkjet ink is a pigment, then the curable inkjet ink preferably contains a dispersant, more preferably a polymeric dispersant, for dispersing the pigment.

Suitable polymeric dispersants are copolymers of two monomers but they may contain three, four, five or even more monomers. The properties of polymeric dispersants depend on both the nature of the monomers and their distribution in the polymer. Copolymeric dispersants preferably have the following polymer compositions:
statistically polymerized monomers (e.g. monomers A and B polymerized into ABBAABAB);
alternating polymerized monomers (e.g. monomers A and B polymerized into ABABABAB);
gradient (tapered) polymerized monomers (e.g. monomers A and B polymerized into AAABAABBABBB);
block copolymers (e.g. monomers A and B polymerized into AAAAABBBBBB) wherein the block length of each of the blocks (2, 3, 4, 5 or even more) is important for the dispersion capability of the polymeric dispersant;
graft copolymers (graft copolymers consist of a polymeric backbone with polymeric side chains attached to the backbone); and
mixed forms of these polymers, e.g. blocky gradient copolymers.

Suitable polymeric dispersants are listed in the section on “Dispersants”, more specifically [0064] to [0070] and [0074] to [0077], in EP-A 1911814.

Commercial examples of polymeric dispersants are the following:
DISPERBYK™ dispersants available from BYK CHEMIE GMBH;
SOLSPERSE™ dispersants available from NOVEON;
TEGO™ DISPERS™ dispersants from EVONIK;
EDAPLAN™ dispersants from MÜNZING CHEMIE;
ETHACRYL™ dispersants from LYONDELL;
GANEX™ dispersants from ISP;
DISPEX™ and EFKA™ dispersants from CIBA SPECIALTY CHEMICALS INC;
DISPONER™ dispersants from DEUCHEM; and
JONCRYL™ dispersants from JOHNSON POLYMER.

### Surfactants

The curable inkjet composition may contain at least one surfactant, which may act as wetting agent, dispersant or emulsifier.

The surfactant can be anionic, cationic, non-ionic, or zwitter-ionic.

Suitable surfactants include fluorinated surfactants, fatty acid salts, ester salts of a higher alcohol, alkylbenzene sulfonate salts, sulfosuccinate ester salts and phosphate ester salts of a higher alcohol (for example, sodium dodecylbenzenesulfonate and sodium dioctylsulfosuccinate), ethylene oxide adducts of a higher alcohol, ethylene oxide adducts of an alkylphenol, ethylene oxide adducts of a polyhydric alcohol fatty acid ester, and acetylene glycol and ethylene oxide adducts thereof (for example, polyoxyethylene nonylphenyl ether, and SURFYNOL™ 104, 104H, 440, 465 and TG available from AIR PRODUCTS & CHEMICALS INC.).

Preferred surfactants are selected from fluorinated surfactants (such as fluorinated hydrocarbons) and silicone surfactants. The silicone surfactants are preferably siloxanes and can be alkoxylated, polyether modified, polyether modified hydroxy functional, amine modified, epoxy modified and other modifications or combinations thereof. Preferred siloxanes are polymeric, for example polydimethylsiloxanes.

Preferred commercial silicone surfactants include BYK™ 333, BYK™ 347 and BYK™ UV3510 from BYK Chemie.

In a preferred embodiment, the surfactant is a polymerizable compound.

Preferred polymerizable silicone surfactants include a (meth)acrylated silicone surfactant. Most preferably the (meth)acrylated silicone surfactant is an acrylated silicone surfactant, because acrylates are more reactive than methacrylates. Examples are BYK™ 3566 from BYK Chemie and Ebecryl 1360 from Allnex. A preferred commercial acrylated surfactant is Ebecryl 1360 from Allnex.

In a preferred embodiment, the (meth)acrylated silicone surfactant is a polyether modified (meth)acrylated polydimethylsiloxane or a polyester modified (meth)acrylated polydimethylsiloxane.

Preferably the surfactant is present in the curable inkjet composition in an amount of 0 to 3 wt % based on the total weight of the curable inkjet composition.

### Preparation of the Inkjet Composition

The preparation of pigmented curable inkjet inks is well-known to the skilled person. Preferred methods of preparation are disclosed in paragraphs [0076] to [0085] of WO2011/069943.

### Method of Manufacturing an Electronic Device

The method of manufacturing an electronic device according to the present invention includes at least one step wherein a curable inkjet composition as described above is jetted and cured on a substrate.

According to a preferred embodiment, the electronic device is a Printed Circuit Board (PCB).

In a particular preferred embodiment, the method of manufacturing a PCB includes a step wherein the solder mask composition is applied on the substrate via an inkjet printing step, followed with a UV-curing step and a heat treatment step.

The substrate is preferably a dielectric substrate containing an electrically conductive pattern, which typically comprises conductive pads electrically connected with each other using traces.

The dielectric substrate of the electronic device may be any non-conductive material. The substrate is typically a paper/resin composite or a resin/fibre glass composite, a ceramic substrate, a polyester or a polyimide. FR-4 is an example of a material frequently used as dielectric substrate.

The electrically conductive pattern is typically made from any metal or alloy which is conventionally used for preparing electronic devices such as gold, silver, palladium, nickel/gold, nickel, tin, tin/lead, aluminium, tin/aluminium and copper. The electrically conductive pattern is preferably made from copper.

Before applying the solder mask composition, the substrate is preferably subjected to one or more pre-treatment processes. These processes can be mechanical or chemical, or a combination thereof. A preferred pre-treatment process is chemical micro-etching, which typically results in micro-roughness on the substrate. A so-called anti-bleeding treatment can be additionally applied to the micro-etched surface to prevent bleeding of the ink into the micro-pores and to improve print quality. This anti-bleeding treatment typically comprises applying a coating layer on the substrate in order to adjust its surface energy, resulting in sharper contact angles and minimal bleeding of ink into micro-pores. Anti-bleeding treatments are preferably used when printing low-viscous compositions.

The process of inkjet printing the solder mask layer on a dielectric substrate with an electrically conductive pattern preferably comprises one or more printing steps as listed below.
The printing of so-called “ramps” comprises printing lines next to the copper traces. This preparative printing step ensures a sufficient coverage of the Cu traces. If no ramps are printed next to the copper traces, the cured solder mask may be too thin on the edges (also called shoulders) of the copper traces. The thickness of the printed ramps is related to the height of the plated Cu traces. For plated Cu traces having a large height, a higher ramp ink thickness is required in order to have sufficient coverage on the Cu edges. For plated Cu traces with a lower height, a lower ramp thickness may be used. The ramps preferably have a thickness of 0 to 80 μm, more preferably from 10 to 60 μm, most preferably from 20 to 40 μm.
The printing of so-called “dams” is usually done to indicate the contours of the entire solder mask layer. These dams are usually cured with higher curing energies to provide precise features and lines. The thickness of the dams is preferably at least the same as the thickness of the full solder mask layer. The thickness of the dams is more preferably higher than the thickness of the full solder mask layer, in order to avoid possible ink flow towards the open pad. The dams preferably have a thickness of 5 to 75 μm, more preferably from 10 to 60 μm, most preferably from 20 to 40 μm.
Finally, the entire board is printed within the contours of the dams, covering the Cu traces, but leaving open the Cu pads for soldering.

The curable inkjet composition may be cured by exposing the composition to actinic radiation, such as electron beam or ultraviolet (UV) radiation. Preferably the curable inkjet composition is cured by UV radiation, more preferably using UV LED curing. To fixate the curable composition on the substrate, a UV pin curing step may be used immediately after printing. This UV pin curing may improve the print quality.

A heat treatment is preferably applied to the jetted and UV-cured curable inkjet composition. The heat treatment is preferably carried out at a temperature between 80° C. and 250° C. The temperature is preferably not less than 100° C., more preferably not less than 120° C. To prevent charring of the solder mask, the temperature is preferably not higher than 200° C., more preferably not higher than 160° C.

The thermal treatment is typically carried out from 15 to 90 minutes.

The purpose of the thermal treatment is two-fold: curing thermal cross-linking agents present in the curable composition, and further polymerizing potentially non-reacted radiation curable compounds. A dense interpenetrating polymer network can thus be created.

The method of manufacturing a PCB may comprise two, three or more inkjet printing steps. For example, the method may comprise two inkjet printing steps wherein an etch resist is provided on a metal surface in one inkjet printing step and wherein a solder mask is provided on a dielectric substrate containing an electrically conductive pattern in another inkjet printing step.

A third inkjet printing step may be used for legend printing.

### Inkjet Printing Devices

The curable inkjet composition may be jetted by one or more print heads ejecting small droplets in a controlled manner through nozzles onto a substrate, which is moving relative to the print head(s).

A preferred print head for the inkjet printing system is a piezoelectric head. Piezoelectric inkjet printing is based on the movement of a piezoelectric ceramic transducer when a voltage is applied thereto. The application of a voltage changes the shape of the piezoelectric ceramic transducer in the print head creating a void, which is then filled with ink. When the voltage is again removed, the ceramic expands to its original shape, ejecting a drop of ink from the print head. However, the inkjet printing method according to the present invention is not restricted to piezoelectric inkjet printing. Other inkjet print heads can be used and include various types, such as a continuous type.

The inkjet print head normally scans back and forth in a transversal direction across the moving ink-receiving surface (substrate). Often the inkjet print head does not print on the way back. Bi-directional printing is preferred for obtaining a high areal throughput. Another preferred printing method is by a “single pass printing process”, which can be performed by using page wide inkjet print heads or multiple staggered inkjet print heads which cover the entire width of the ink-receiving surface. In a single pass printing process, the inkjet print heads usually remain stationary and the ink-receiving surface is transported under the inkjet print heads.

### EXAMPLES

### Materials

All materials used in the following examples were readily available from standard sources such as ALDRICH CHEMICAL Co. (Belgium) and ACROS (Belgium) unless otherwise specified. The water used was deionized water.

VMOX is N-vinyl-5-methyl-2-oxazolidinone available from BASF.

DPGDA is dipropylene glycol diacrylate, commercially available as Sartomer™ SR508 from ARKEMA.

VEEA is 2-(vinylethoxy)ethyl acrylate available from NIPPON SHOKUBAI, Japan.

PEGDA is polyethyleneglycol diacrylate available as Sartomer™ SR259 from ARKEMA.

EHMA is 2-ethylhexyl methacrylate.

CTFA is cyclic trimethylolpropane formal acrylate available as Sartomer™ SR531 from ARKEMA.

DAROCUR ITX is an isomeric mixture of 2- and 4-isopropylthioxanthone from BASF.

BAPO is a bis(2,4,6-trimethylbenzoyl)-phenylphosphineoxide photoinitiator available as Irgacure™ 819 from BASF.

BISAPHOS is a flame retardant containing a mixture of aromatic polyphosphates available from ADEKA.

Cymel NF2000A is a triazine cross-linking agent commercially available from ALLNEX.

Trixene BI7960 is a DMP-blocked isocyanate cross-linking agent commercially available from LANXESS.

Cyan is SUN FAST BLUE 15:4, a cyan pigment available from SUN CHEMICALS

Yellow is CROMOPHTAL YELLOW D 1085J, a yellow pigment from BASF.

INHIB is a mixture forming a polymerization inhibitor having a composition according to Table 1.

TABLE 1

| Component | wt % |
|---|---|
| DPGDA | 82.4 |
| p-methoxyphenol | 4.0 |
| 2,6-di-tert-butyl-4-methylphenol | 10.0 |
| Cupferron ™ AL | 3.6 |

Cupferron™ AL is aluminium N-nitrosophenylhydroxylamine from WAKO CHEMICALS LTD.

PRECIP 162 is a dispersing agent and has been precipitated from Disperbyk 162, a dispersant solution available from BYK (ALTANA).

DISP is a solution of 30 wt % PRECIP 162 and 1 wt % INHIB in VEEA.

GD is a green dispersion prepared as follows:

A concentrated green dispersion, GD, was prepared having a composition according to Table 2.

TABLE 2

| Component | wt % |
|---|---|
| Cyan | 7.5 |
| Yellow | 7.5 |
| DISP | 15 |
| INHIB | 1 |
| VEEA | 69 |

GD was prepared as follows: 138 g of VEEA, 2 g of INHIB, 30 g of DISP, 30 g of Cyan and 30 g of Yellow were mixed using a DISPERLUX™ dispenser. Stirring was continued for 30 minutes. The vessel was connected to a NETZCH MiniZeta mill filled with 900 g of 0.4 mm yttrium stabilized zirconia beads (“high wear resistant zirconia grinding media” from TOSOH Co.). The mixture was circulated over the mill over 120 minutes (residence time of 45 minutes) and a rotation speed in the mill of about 10.4 m/s. During the complete milling procedure, the content in the mill was cooled to keep the temperature below 60° C. After milling, the dispersion was discharged into a vessel.

### Evaluation Methods

### Viscosity

The viscosity of the inks was measured at 45° C. and at a shear rate of 1000 s⁻¹ using a HAAKE RotoVisco 1.

For industrial inkjet printing, the viscosity at 45° C. and at a shear rate of 1000 s⁻¹ is preferably between 5.0 and 15 mPa·s. More preferably the viscosity at 45° C. and at a shear rate of 1000 s⁻¹ is less than 15 mPa·s.

### LED Sensitivity

To evaluate the LED sensitivity of the inks, the inkjet inks were coated using a barcoater and a Braive automatic film applicator on a PET substrate. The bar coater resulted in coatings of 10 μm thick which were cured using a Fusion LED station (UV LED lamp 12 W). The coatings were passed through the LED light using a belt which was set at moving 50 m/min and the LED light power was set at 4 W.

After coating and curing, the inks were evaluated using a Q tip. The Q tip was used to wipe the coating and a score was given according below:
0: No wipe visible on coating
1: Wipe visible on coating but no ink on the Q tip
2: Wipe visible on coating and ink on Q tip but no damage on the coating
3: Ink on Q tip and minor damage on the coating
4: Ink on Q tip and major damage on the coating
5: Ink completely removed after wiping with Q tip

### ENIG Resistance

An ENIG simulation was carried out using a procedure as described below:
The boards were dipped in a bath of acid cleaner (Umicore cleaner 865) at 40° C. during 4 min. The boards were then removed and dipped in a rinsing bath of deionized water (DW) at room temperature (RT) during 90 seconds.
The boards were dipped in a microetching bath comprising 8.5 wt % Na2S208 and ±3.2 wt % H₂SO₄ (98%) in water at a temperature between 26-33° C. for 100 s. The boards were then removed and rinsed in DW at RT during 90 seconds.
The boards were dipped in a 2.5 wt % aqueous H₂SO₄ solution at RT during 30 seconds, after which they were removed and rinsed in DW at RT for 90 seconds. They were dipped again in the same solution for 60 seconds before being transferred to the palladium bath.
The boards were dipped in a palladium activator bath (Accemulta MKN 4) at a temperature around 30° C. for 90 s followed by dipping in a 5 wt % aqueous H₂SO₄ solution at RT during 75 seconds. The boards were then removed and dipped in a rinsing bath of DW at RT during 90 seconds.
Then the boards were dipped in a nickel bath (Nimuden NPR 4) at a temperature around 85° C. for 35 min. The boards were then removed and dipped in a rinsing bath of DW at RT during 90 s.
Finally, the boards were dipped in a gold bath (Gobright TAM 55) at a temperature around 80° C. for 12 min. The boards were then removed and dipped in a rinsing bath of DW at RT during 90 s.

After ENIG treatment, it is possible that so-called blistering occurs, especially around open pads. In these areas, it appears that the ENIG solution penetrates and lifts up the solder mask layer. Besides blistering, it is also possible that a so-called “halo effect” is observed as an area around an open pad having a different appearance. Both phenomena could create weak adhesion points of the solder mask onto the substrate and may result in peeling off of the layer.

The occurrence of blisters and halo effect was evaluated microscopically with a digital microscope Dino-LITE and scored with a value from 0 to 5, depending on the observed blistering density and width of the halo:
0: No blistering and no halo.
1: Blistering density less than 5% of the ink layer and/or halo width less than 1 mm.
2: Blistering density less than 5-15% of the ink layer and/or halo width from 1 mm to 2 mm.
3: Blistering density less than 15-35% of the ink layer and/or halo width from 2 mm to 3 mm.
4: Blistering density less than 35-65% of the ink layer and/or halo width from 2 mm to 4 mm.
5: Blistering density more than 65% of the ink layer and/or halo width more than 4 mm.

### Comparative Examples 1 to 2 and Examples 1 to 5

The curable inkjet compositions Ex-1 to Ex-5 and the comparative curable inkjet compositions Comp-1 to Comp-2 were prepared according to Table 3. The weight percentages are based on the total weight of the curable inkjet composition.

TABLE 3

| | Comp-1 | Comp-2 | Ex-1 | Ex-2 | Ex-3 | Ex-4 | Ex-5 |
|---|---|---|---|---|---|---|---|
| GD | 6.6 | 6.6 | 6.6 | 6.6 | 6.6 | 6.6 | 6.6 |
| VEEA | 38.8 | 28.8 | 36.3 | 33.80 | 28.8 | 18.8 | 8.8 |
| PEGDA | 30.0 | 30.0 | 30.0 | 30.0 | 30.0 | 30.0 | 30.0 |
| EHMA | 5.0 | 5.0 | 5.0 | 5.0 | 5.0 | 5.0 | 5.0 |
| VMOX | — | — | 2.5 | 5.0 | 10.0 | 20.0 | 30.0 |
| CTFA | — | 10 | — | — | — | — | — |
| DAROCUR | 0.6 | 0.6 | 0.6 | 0.6 | 0.6 | 0.6 | 0.6 |
| ITX | | | | | | | |
| BAPO | 4.7 | 4.7 | 4.7 | 4.7 | 4.7 | 4.7 | 4.7 |
| Trixene | 7.0 | 7.0 | 7.0 | 7.0 | 7.0 | 7.0 | 7.0 |
| BI7960 | | | | | | | |
| Cymel | 2.4 | 2.4 | 2.4 | 2.4 | 2.4 | 2.4 | 2.4 |
| NF2000A | | | | | | | |
| INHIB | 0.9 | 0.9 | 0.9 | 0.9 | 0.9 | 0.9 | 0.9 |
| BISAPHOS | 2 | 2 | 2 | 2 | 2 | 2 | 2 |
| Viscosity | 5.65 | 6.32 | 5.73 | 5.81 | 6.12 | 6.25 | 6.36 |
| (mPa · s) | | | | | | | |

The LED sensitivity was evaluated as described above and the results are shown further in Table 4.

The inkjet inks were then printed using a MicroCraft CPS2013D (Printhead Konica Minolta KM1024iS, UV LED 395 12 W total output of the lamp) on a checkerboard (copper plated on FR4) substrate from Eurocircuits to obtain a soldermask layer having a final thickness of +/−22 μm. The checkerboards include a 35 μm copper layer that was roughened by chemical etching. Before the chemical etching, the checkerboards were dipped during 30 seconds in an acid cleaner bath activated with air bubbling (MEKLEEN MAC-5330RTU which is a solution of about 12-15% H₂SO₄ and about 4-6% H₂O₂ in demineralized water commercially available from MEC Europe), and afterwards rinsed with demineralized water. In the chemical etching step, the substrate was transported through a Bungard Sprint 3000 Conveyorized Spray Etch machine at a speed of 0.4 m/min while spraying with the chemical etchant CZ2001 (available from MEC) heated at 30° C. After a rinsing step with demineralized water an extra spraying step with 1M HCl was carried out, followed again by a rinsing step with demineralized water and an anti-bleeding treatment step, where the substrate is dipped during 30 seconds in the anti-bleeding solution (a 25 v/v % of CL-8320C in demineralized water, pH 7.5, commercially available from MEC Europe). The substrate is then again rinsed with demineralized water and finally dried in an Air 2000 dryer (available from Bungard). The substrate was printed within 24 h after this pretreatment.

After printing the samples were baked in an oven at 150° C. for 1 hour.

Different printing protocols were used:
Print-1 (P1): An image having a resolution 1440 dpi in the x-direction and 1440 dpi in the y-direction was printed and cured. The UV energy applied corresponded to 10% of the total power of the 12 W lamp. A final cure was applied to further cure the printed solder mask layer (4 passes at full energy of the 12 W lamp).
Print-2 (P2): Compared to Print 1, the image was printed in the same resolution but with the difference that the UV energy applied corresponded to 100% of the total power of the 12 W lamp. A final cure was then carried out as described for Print-1.
Print-3 (P3): Compared to Print 1 and 2, the image was printed in two passes to achieve a certain thickness. In the first pass an image having a resolution 1440 dpi in the x-direction and 1080 dpi in the y-direction was printed and cured. The UV energy applied corresponded to 100% of the total power of the 12 W lamp. In the second pass an image having a resolution 720 dpi in the x-direction and 1080 dpi in the y-direction was printed and cured. The UV energy applied corresponded to 0% of the total power of the 12 W lamp. A final cure was then carried out as described for Print-1.

ENIG resistance was evaluated as described above. The results are also given in Table 4.

TABLE 4

| | LED sensitivity | | | | ENIG Resistance | | |
|---|---|---|---|---|---|---|---|
| | 1 pass | 2 pass | 3 pass | 4 pass | P1 | P2 | P3 |
| Comp-1 | 5 | 5 | 2 | 2 | 5 | 5 | 3 |
| Comp-2 | 5 | 5 | 3 | 3 | 2 | 1 | 2 |
| Ex-1 | 5 | 5 | 2 | 2 | 3 | 3 | 3 |
| Ex-2 | 5 | 4 | 2 | 2 | 3 | 2 | 3 |
| Ex-3 | 5 | 2 | 2 | 2 | 2 | 2 | 3 |
| Ex-4 | 5 | 2 | 2 | 2 | 2 | 2 | 3 |
| Ex-5 | 5 | 2 | 2 | 2 | 4 | 3 | 4 |

From Table 4 it is clear that inks containing VMOX (Ex-1 to Ex-5) have a better ENIG resistance than inks without VMOX (Comp-1).

Table 4 further shows that the presence of VMOX improves the LED sensitivity while maintaining a good ENIG resistance. The improved LED sensitivity in combination with a good ENIG resistance is observed for inks having from 5 to 30 wt % of VMOX.

Comp-2 has an identical composition as Ex-3, with the only difference that Comp-2 comprises CTFA instead of VMOX. Comp-2 has a good ENIG resistance, but a bad LED sensitivity, even at 3 and 4 passes.

1-15. (canceled)

16. A curable inkjet composition for a printed circuit board comprising:
(a) one or more thermal cross-linking agents selected from the group consisting of an unblocked isocyanate, a blocked isocyanate, and a triazine compound; and
(b) at least two photopolymerizable compounds, characterized in that at least one photopolymerizable compound has a chemical structure according to General Formula I: 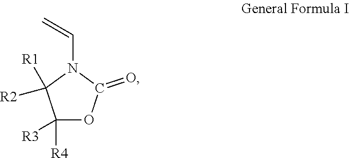
wherein R1, R2, R3, and R4 independently from each other represent hydrogen or a substituted or unsubstituted C₁ to C₁₀ alkyl group.

17. The curable inkjet composition of claim 16, wherein the amount of the photopolymerizable compound according to General Formula I is from 5 to 30 wt % relative to the total weight of the inkjet composition.

18. The curable inkjet composition of claim 17, wherein the photopolymerizable compound according to General Formula I is N-vinyl-5-methyl-2-oxazolidinone.

19. The curable inkjet composition of claim 16, wherein at least one thermal cross-linking agent is a blocked isocyanate.

20. The curable inkjet composition of claim 19, wherein the blocked isocyanate is a blocked HDI oligomer, wherein the oligomer is selected from the group consisting of a biuret, a trimethylolpropane adduct, and an isocyanurate.

21. The curable inkjet composition of claim 16, wherein at least one thermal cross-linking agent is a triazine compound.

22. The curable inkjet composition of claim 21, wherein the triazine compound has a chemical structure according to General Formula III: 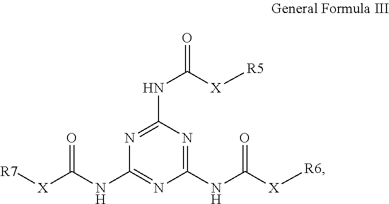
wherein
X represents N, O, S, P, or C; and
R5, R6, and R7 independently from each other represent a substituted or unsubstituted alkyl group.

23. The curable inkjet composition of claim 16, wherein at least one photopolymerizable compound is a multifunctional polymerizable compound.

24. The curable inkjet composition of claim 23, wherein the multifunctional photopolymerizable compound is selected from the group consisting of 2-(2′-vinyloxyethoxy)ethylacrylate, polyethyleneglycol diacrylate, hexanediol diacrylate, trimethylolpropane triacrylate, pentaerythritol tetraacrylate, dipentaerythritol pentaacrylate, polyester acrylate oligomer, and polyether acrylate oligomer.

25. The curable inkjet composition of claim 16, having a viscosity of 5 to 15 mPa·s measured at 45° C. at a shear rate of 1000 s⁻¹.

26. A method for manufacturing a printed circuit board comprising an inkjet printing step wherein a curable inkjet composition as defined in claim 16 is jetted and cured on a substrate.

27. The method of claim 26, further comprising a heating step.

28. The method of claim 27, wherein the heating step is carried out at a temperature from 80° C. to 250° C.

29. The method of claim 26, wherein the substrate is a dielectric substrate provided with an electrically conductive circuitry.

30. A PCB board comprising a solder mask, wherein the solder mask is obtained using the curable inkjet composition according to claim 16.

31. A PCB board comprising a solder mask, wherein the solder mask is obtained using the curable inkjet composition according to claim 17.

32. A PCB board comprising a solder mask, wherein the solder mask is obtained using the curable inkjet composition according to claim 18.

33. A PCB board comprising a solder mask, wherein the solder mask is obtained using the curable inkjet composition according to claim 19.

34. A PCB board comprising a solder mask, wherein the solder mask is obtained using the curable inkjet composition according to claim 20.

35. A PCB board comprising a solder mask, wherein the solder mask is obtained using the curable inkjet composition according to claim 21.
